(19) United States
(12) Patent Application Publication
(10) Pub. No.: US 2026/0231802 A1
(43) Pub. Date: Aug. 6, 2026

(54) PICK-AND-PLACE TOOL AND PROCESS OF USING THE SAME

(71) Applicant: TAIWAN SEMICONDUCTOR MANUFACTURING COMPANY LTD., HSINCHU (TW)

(72) Inventors: TZU JUNG TIEN, HSINCHU COUNTY (TW); JEN-YUAN CHANG, HSINCHU CITY (TW)

(21) Appl. No.: 19/046,458

(22) Filed: Feb. 5, 2025

(51) Int. Cl. H01L 23/00

(52) U.S. Cl. CPC H10W 72/011; H10W 99/00; H10W 72/019; H10W 72/071; H10W 72/90; H10W 80/161; H10W 80/163; H10W 80/301; H10W 90/794

(57) ABSTRACT

A pick-and-place tool is provided. The pick-and-place tool includes a gantry, a moving arm and a plurality of extending arms. The moving arm is horizontally-movably attached to the gantry. The plurality of extending arms extend from a bottom of the moving arm. Each of the plurality of extending arms comprises a telescopic shaft and a bond head. The telescopic shaft extends from the bottom of the moving arm and is horizontally movable and vertically retractable. The bond head extends from a bottom end of the telescopic shaft.

### BACKGROUND

An integrated circuit that compresses all of a system's required components onto one piece of chip, which is known to be fabricated using hybrid die-to-die bonding processes. To achieve well bonding between the dice, pick and place processes require extreme precision to prevent misalignment between the dice. Therefore, when the pick and place processes are disturbed, the picked die must be scrapped because the picked die cannot be accurately realigned, resulting in decreased manufacturing yield.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a schematic side view of a pick-and-place tool, in accordance with some embodiments of the present disclosure.

FIG. 2 illustrates a schematic side view of the pick-and-place tool shown in FIG. 1, in accordance with some embodiments of the present disclosure.

FIG. 3 illustrates an enlarged side view of the circulated portion A of the pick-and-place tool as shown in FIG. 2, in accordance with some embodiments of the present disclosure.

FIG. 4 illustrates a schematic side view of a pick-and-place tool in accordance with some another embodiments of the present disclosure.

FIG. 5 illustrates a side view of a pick-and-place tool in accordance with some alternative embodiments of the present disclosure.

FIGS. 6A to 6D illustrate schematic side views of various pick-and-place tools during operation, in accordance with some embodiments of the present disclosure.

FIG. 7 is a flowchart of a process for picking and placing device dies in accordance with some embodiments of the present disclosure.

FIGS. 8A to 8H illustrate various perspective views of picking and placing device dies at various stages according to the process of FIG. 7.

FIGS. 9A to 9I illustrate various schematic views of picking and placing device dies various stages according to the process of FIG. 7.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

Manufacturing of integrated circuits often involves a bonding of device dies to package substrates. In a typical bonding process, a device die is picked up from a wafer that has already been sawed into dies. The device die is flipped upside down and placed on a table. A bond head then picks up the flipped device die from the table, and then places the device die on a package substrate. Accuracy in the placement of the device die on the package substrate needs to be well controlled to maintain the yield of the bonding process. To maintain accuracy, only one device die can be picked up from the table and placed onto a package substrate. To increase throughput of the pick-and-place process, moving speed of the bond head needs to be increased. However, the increased moving speed results in sacrifice in the accuracy of the placement. Therefore, the requirement in the accuracy of the placement conflicts with the requirement of the increasing the throughput. There is a need to improve the throughput of the pick-and-place process while maintain the accuracy of the placement.

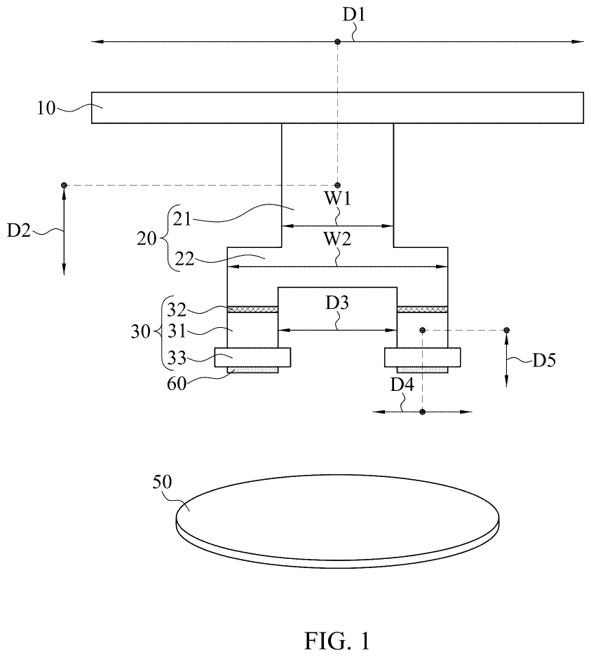

FIG. 1 illustrates a schematic side view of a pick-and-place tool according to some embodiments of the present disclosure located above a substrate 50. The pick-and-place tool comprises a gantry 10, a moving arm 20 and a plurality of extending arms 30.

The gantry 10 is used to hold the moving arm 20, so that the moving arm 20 can move along the gantry 10. For example, the gantry 10 may comprise a rail, a driven member or the like, so that the moving arm 20 can be movably attached to the gantry 10. The gantry 10 has a length sufficient for the moving arm 20 to move between device dies 60 to be transferred and the substrate 50 for receiving the device dies 60.

The moving arm 20 is horizontally-movably attached to the gantry 10 and may be extended from the gantry 10 along a “vertical” direction (i.e., z-direction). A top of the moving arm 20 is attached to the gantry 10. In some embodiments, the moving arm 20 can horizontally move (along horizontal directions, including an x-direction, a y-direction and/or a xy direction) within a first distance D1 ranging from about 30 cm to about 2 m. In some embodiments, the first distance D1 may range from between 40 cm to about 1.5 m. In some embodiments, the first distance D1 may range from about 50 cm to about 1 m. In some embodiments, the first distance D1 may range from about 50 mm to about 80 mm. Furthermore, the moving arm 20 may move along the z-direction for a second distance D2 ranging from about 1 cm to about 1 m. In some embodiments, the second distance D2 may range from about 10 cm to about 80 cm. In some embodiments, the second distance D2 may range from about 20 cm to about 60 cm. In some embodiments, the moving arm 20 may be retractable. In some another embodiments, the gantry 10 may be driven to move along the z direction and thus the moving arm 20 attached to the gantry can move along the z-direction along with the gantry 10.

The moving arm 20 may have various shape, which can be a cylinder, a prism (such as a triangular prism, a quadrilateral prism, a pentagonal prism, a hexagonal prism or other polygonal prisms), or other irregular shape. For example, as shown in FIG. 1, the moving arm 20 may have a reversed-T cross section including a shaft portion 21 and a platform portion 22. The shaft portion 21 has a first end, which is horizontally-movably mounted on the gantry 10 and may be retractable. The platform portion 22 extends from a second end of the shaft portion 21 opposite to the first end and has a width W2 larger than a width W1 of the shaft portion 21 so as to present the reversed-T cross section. The width of the platform portion 22 may depend on the number and the size of the plurality of extending arms 30 extending from the platform portion 22. In some embodiments, a ratio of the width W2 of the platform portion 22 to the width W1 of the shaft portion 21 may range from about 20:1 to about 20:19. In some embodiments, the ratio of the width W2 of the platform portion 22 to the width W1 of the shaft portion 21 may range from about 10:1 to about 10:9. In some embodiments, the ratio of the width W2 of the platform portion 22 to the width W1 of the shaft portion 21 may range from about 5:1 to about 5:4. These are, of course, merely examples and are not intended to be limiting.

The plurality of extending arms 30 may be extended from a bottom of the moving arm 20 and may be separated from each other with third distance D3, which may be equal to or greater than a width of the device die 60. In some embodiments, the device die 60 may have a first width, e.g., in the x-direction, which may be between about 1,000 μm and about 26,000 μm, such as about 10,000 μm. The device die 60 may have a second width (or length), e.g., in a Y direction, which may be between about 1,000 μm and about 33,000 μm, such as about 10,000 μm. Other dimensions for the device die 60 may be used. In some embodiments, the device die 60 may include a logic device or memory device such as memory cells including, and not limited to, Static Random Access Memory (SRAM) cells, Dynamic Random Access Memory (DRAM) Cells, Magneto-Resistive Random Access Memory (MRAM) cells, or the like. The device die 60 may include other types of devices. Therefore, the third distance D3 may be equal to or greater than about 1,000 μm and about 33,000 μm.

Each of the plurality of extending arms 30 comprises a telescopic shaft 31, at least one shaft controller 32 and a bond head 33. The telescopic shaft 31 is extended from the bottom of the moving arm 20 and can be elongated along the z direction and can horizontally move (along the x-direction, the y-direction and/or xy direction). In some embodiments, the telescopic shaft 31 can horizontally move (along the x-direction, the y-direction and/or the xy direction) within a fourth distance D4 ranging from about 0.01 μm to about 10 cm. In some embodiments, the fourth distance D4 may range from about 0.05 μm to about 8 cm. In some embodiments, the fourth distance D4 may range from about 0.1 μm to about 5 cm. In some embodiments, the telescopic shaft 31 can move along the z-direction within a fifth distance D5 ranging from about 0.05 mm to about 50 cm. In some embodiments, the fifth distance D5 ranges from about 0.5 mm to about 30 cm. In some embodiments, the fifth distance D5 ranges from about 5 mm to about 15 cm. In some embodiments, the fifth distance D5 ranges from about 1 cm to about 10 cm.

Compared to the first distance D1, which is the distance of the moving arm 20 that can horizontally move, the telescopic shaft 31 can horizontally move with a less distance. Compared to the second distance D2, which is the distance of the moving arm 20 that can vertically move, the telescopic shaft 31 can vertically move with a less distance. Therefore, the telescopic shaft 31 can be accurately positioned when picking or placing the device dies 60. The fourth distance D4 can be less than the first distance D1, and the second distance D2 can be less than the fifth distance D5. In some embodiments, a ratio of the fourth distance D4 to the first distance D1 may range from about 1:10 to about 1:1,000. In some embodiments, a ratio of the fourth distance D4 to the first distance D1 may range from about 1:10 to about 1:1,000. In some embodiments, the ratio of the fourth distance D4 to the first distance D1 may range from about 1:20 to about 1:700. In some embodiments, the ratio of the fourth distance D4 to the first distance D1 may range from about 1:50 to about 1:500. In some embodiments, a ratio of the fifth distance D5 to the second distance D2 may range from about 1:2 to about 1:1,000. In some embodiments, the ratio of the fifth distance D5 to the second distance D2 may range from about 1:10 to about 1:500. In some embodiments, the ratio of the fifth distance D5 to the second distance D2 may range from about 1:50 to about 1:250.

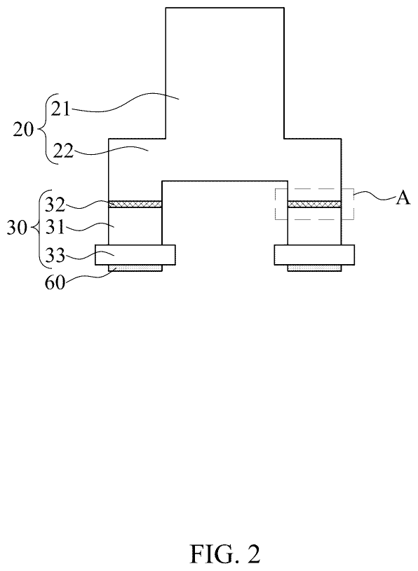

As shown in FIG. 2, the shaft controller 32 can control the movement of the telescopic shaft 31 in the x direction, the y direction, the xy direction and/or the z direction. In some embodiments, the shaft controller 32 may drive the telescopic shaft 31 to rotate along a z axis. The shaft controller 32 may be mounted between the moving arm 20 and the telescopic shaft 31 so as to connect the moving arm 20 with the telescopic shaft 31. In some embodiments, the telescopic shaft 31 may be driven by the shaft controller 32 through a direct drive mode, such as using direct drive motors, a belt drive mechanism, and so on, an indirect drive mode, such as pneumatically, magnetically, electrically driving the telescopic shaft 31, or a hybrid drive mode. These are, of course, merely examples and are not intended to be limiting. For example, the direct drive motor can be a type of permanent-magnet synchronous motor, which can be used to drive gears, racks, chains or the like so as to make the telescopic shaft 31 move horizontally and/or vertically. The belt drive mechanism can directly drive the telescopic shaft 31 to move horizontally and/or vertically.

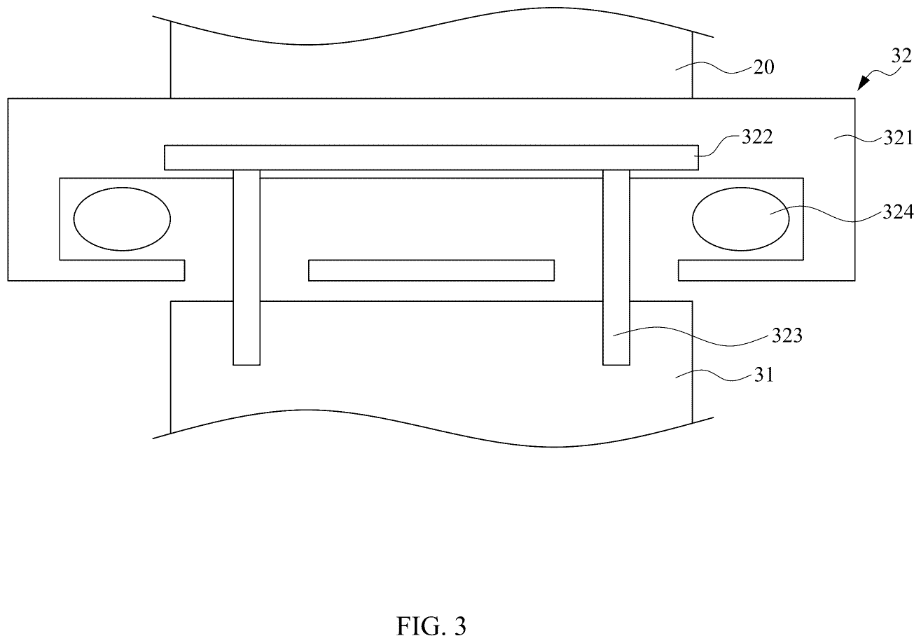

For example, as shown in FIG. 3, the shaft controller 32 may comprise a guide base 321, at least one guide rail 322, at least one connector 323 and electromagnetic induction coils 324. The guide base 321 may be mounted on the bottom of the moving arm 20 and may have a shell-like shape with an inner area. The at least one rail 322 is formed in an inner ceiling of the guide base 321. The number and the pattern of the rail can be varied according to desired movement of the telescopic shaft 31, so that the telescopic shaft 31 may move in the x direction, the y direction, the xy direction and/or the z direction or rotate along the z axis. The at least one connector 323 is movably attached to the at least one rail 322 to connect the guide base 321 with the telescopic shaft 31. In some embodiments, one end of the connector 323 is mounted in the rail 322 while the other end of the connector 323 connects the telescopic shaft 31. In some embodiments, the connector 323 may be elongated along the z direction, so that the telescopic shaft 31 may be elongated along with the elongation of the connector 323. In some embodiments, the elongation movement may be configured to press the device die 60 when placing the device die 60 onto the substrate 50. Since each of the plurality of extending arms 30 has its own telescopic shaft 31 and the connector 323, each of the plurality of extending arms 30 can be pressed with different pressures when the device die 60 is placed onto the substrate 50.

The movement of the connector 323 may be driven through a direct drive mode, an indirect drive mode or a hybrid drive mode as mentioned above. As shown in FIG. 3, the connector 323 can be driven by the electromagnetic induction coils 324. The electromagnetic induction coils 324 are mounted in the inner area of the guide base 321 and can move the connector 323 along the guide rail 322. The electromagnetic induction coils 324 may be controlled by a control element, so that the movement of the telescopic shaft 31 can be controlled by the control element.

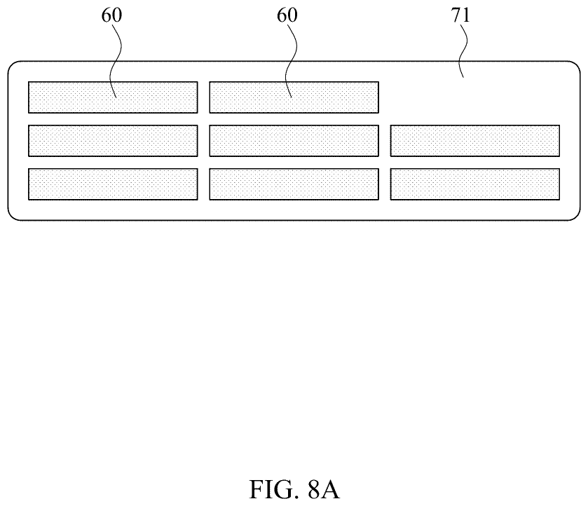

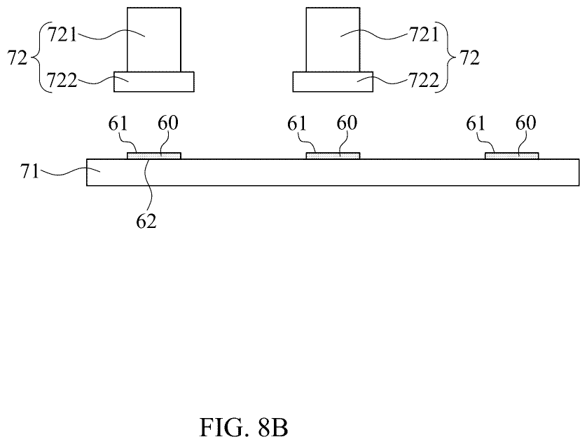

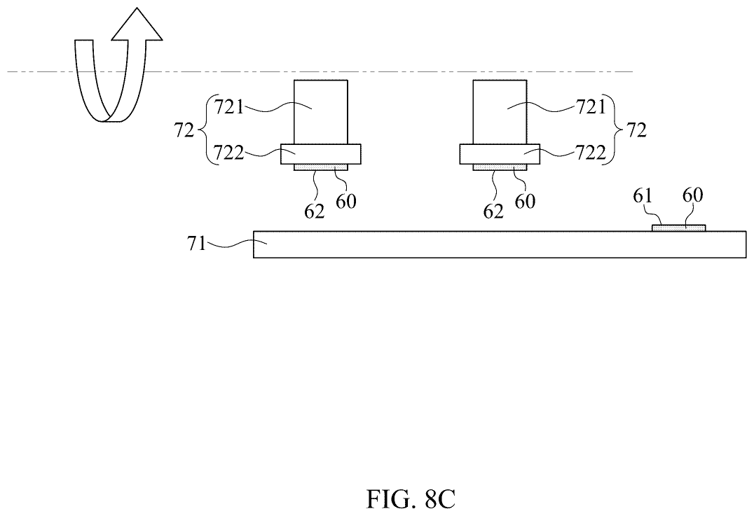

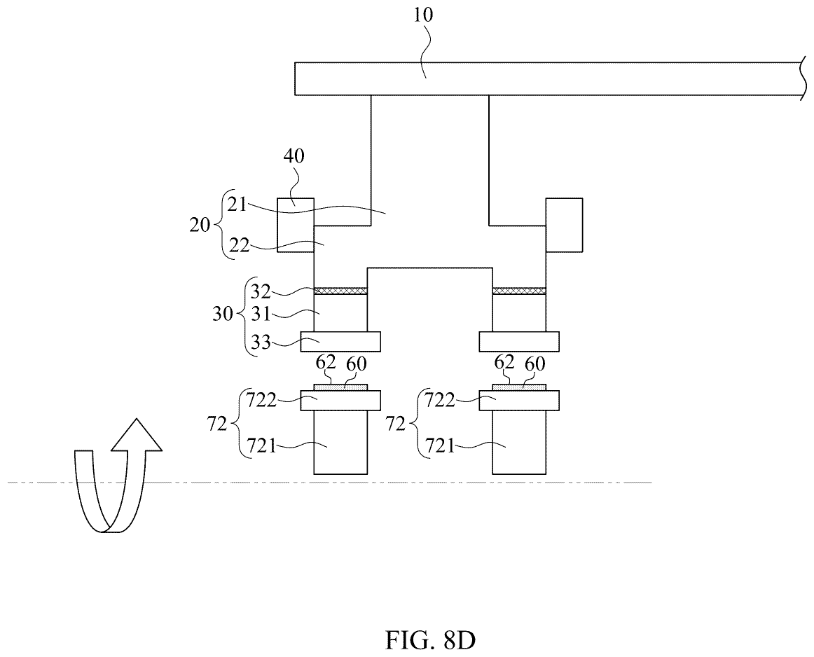

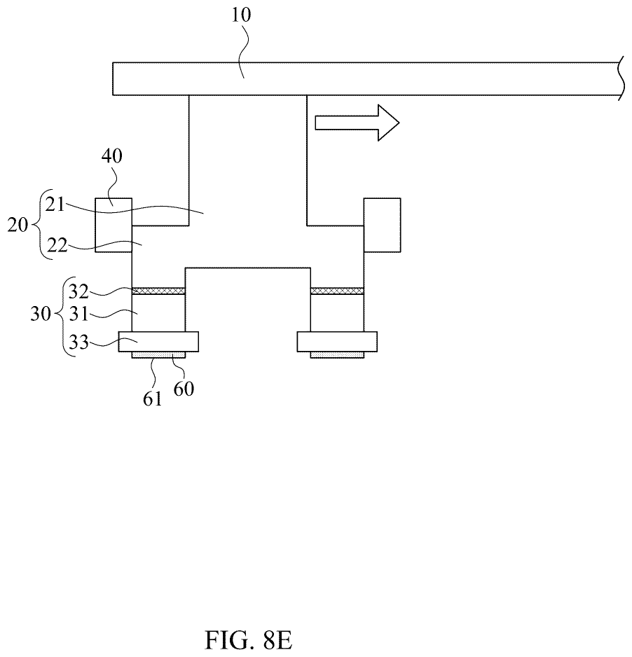

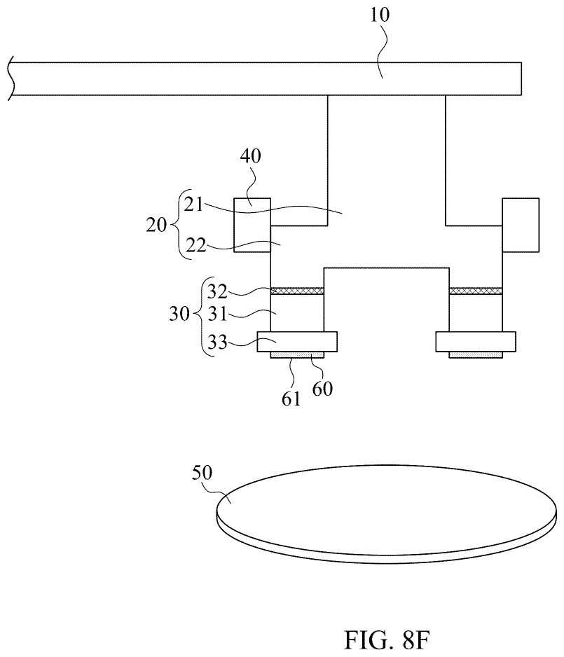

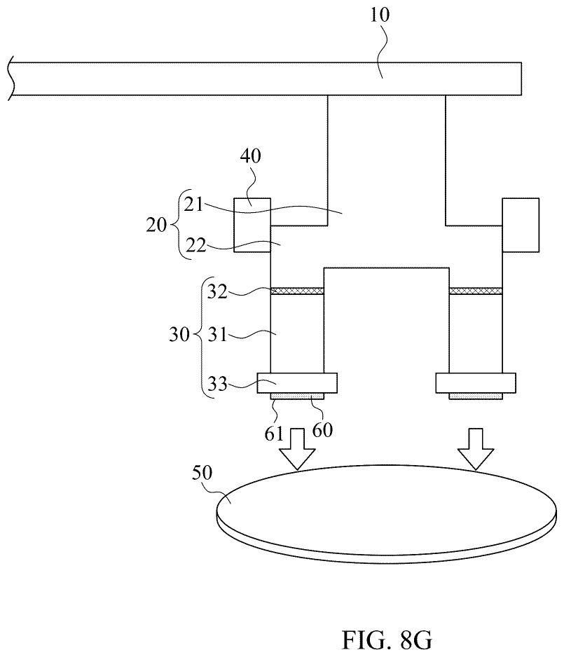

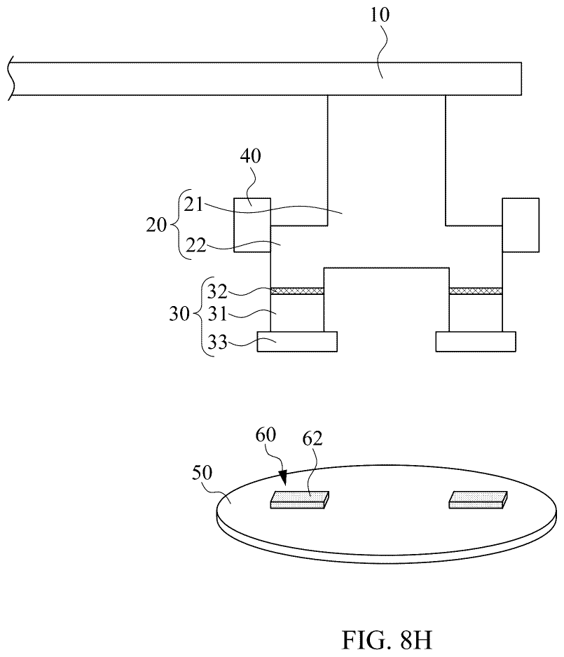

The bond head 33 extends from a bottom end of the telescopic shaft 31 and are movable along with the movement of the telescopic shaft 31. The bond head 33 is used to move the device die 60 from a flipper 72 as shown in FIG. 8D to the substrate 50. The bond head 33 may be a vacuum head capable of picking up die (e.g., the device die 60) through vacuum force. In some embodiments, the bond head 33 may comprise a pressure source, e.g., a vacuum pump. The vacuum pump may be configured to generate a suction force for the bond head 33 to pick up the device die 60. The vacuum pump may be configured to generate or create a vacuum or a relatively low pressure condition inside the bond head 33 compared to an ambient pressure outside of the bond head 33. In some embodiments, the bond head 33 includes or is made of metal. The metal may be stainless steel, aluminum, or the like.

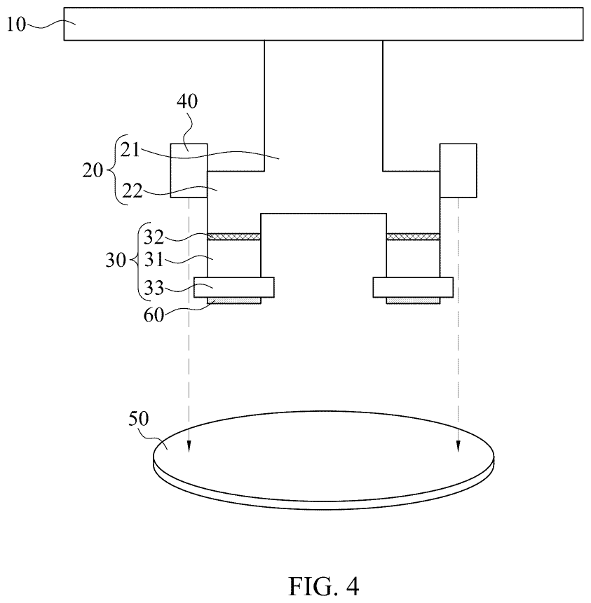

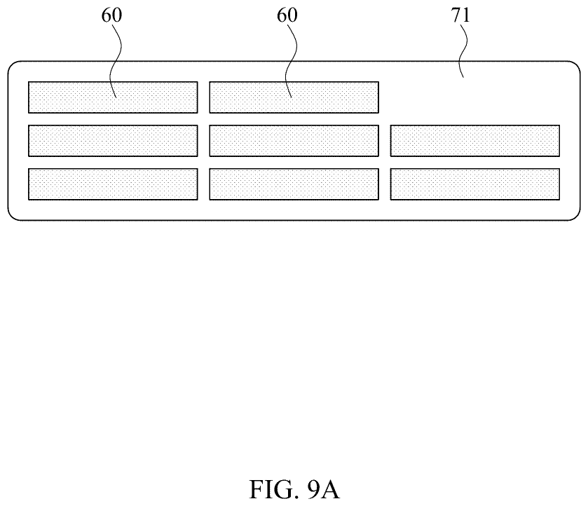

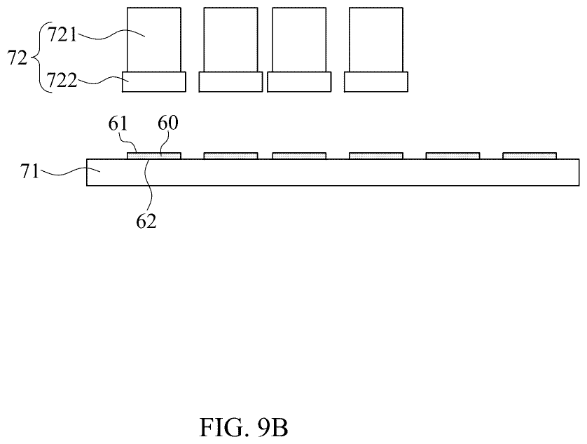

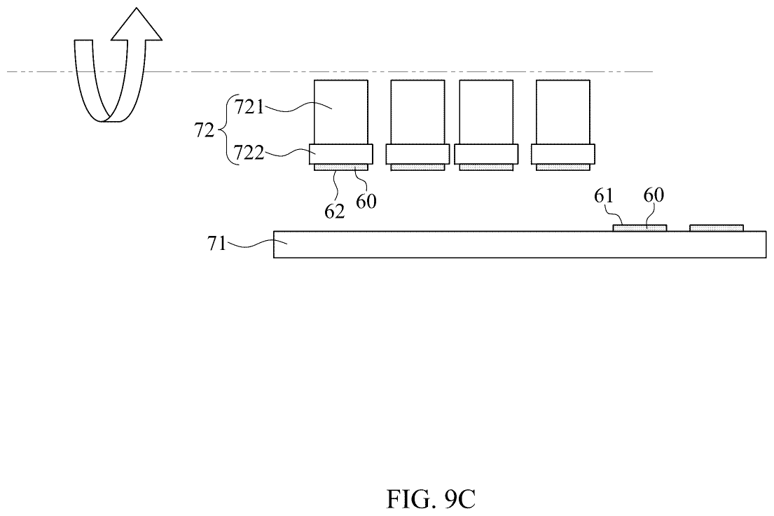

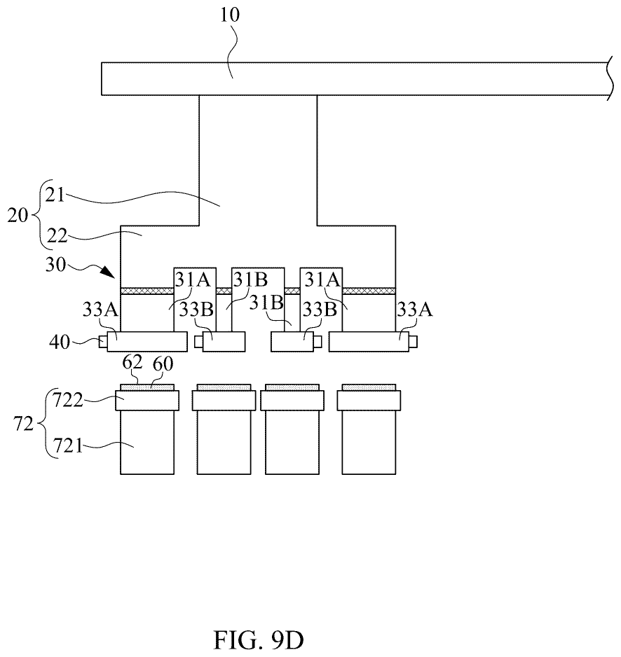

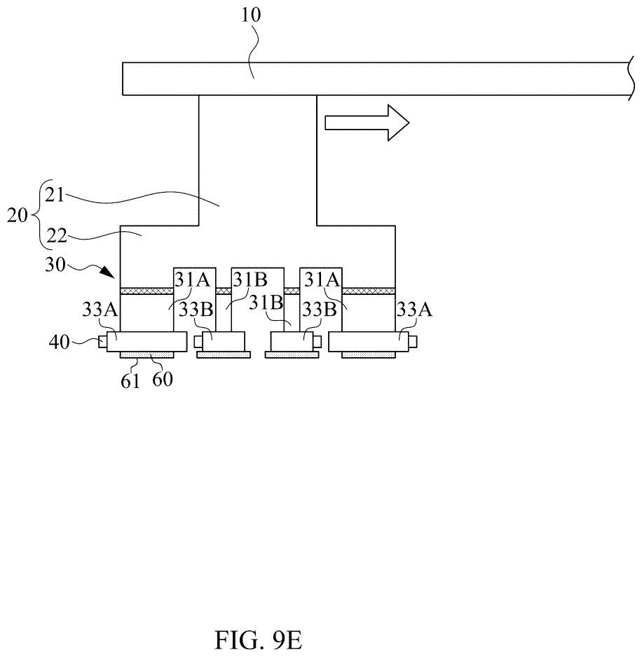

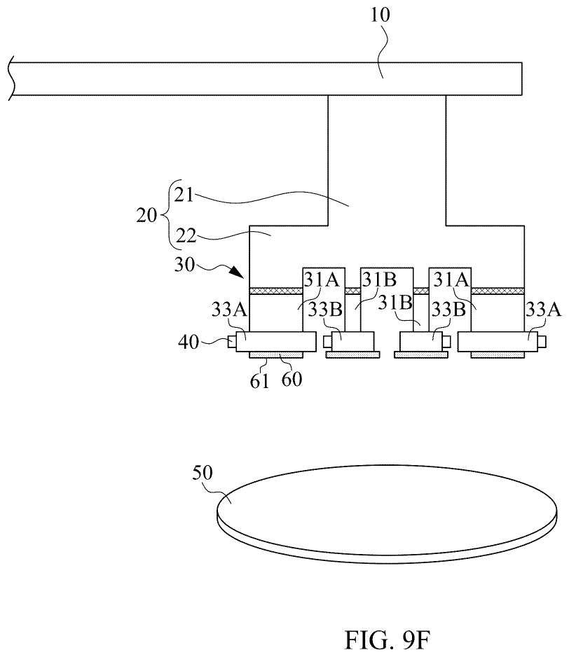

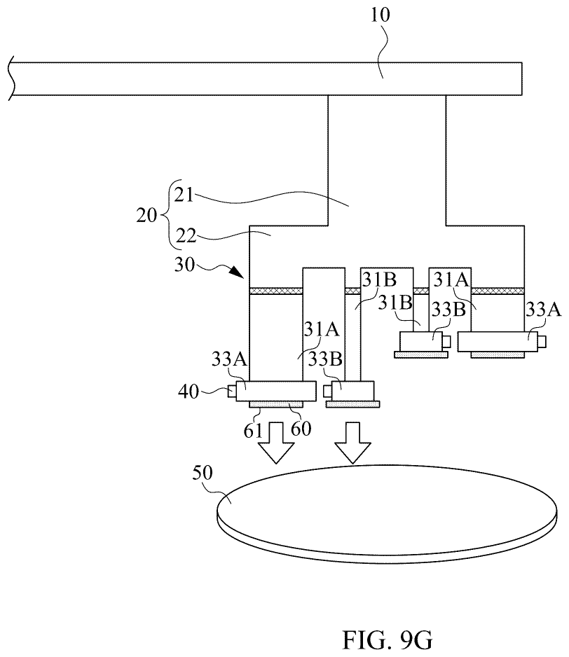

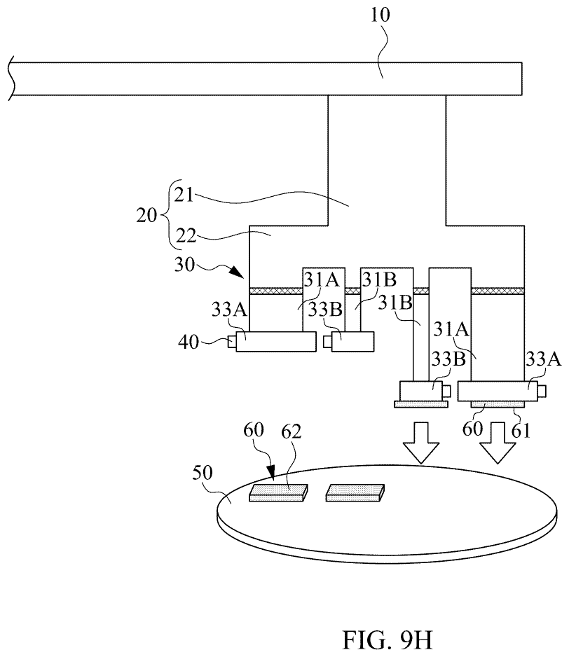

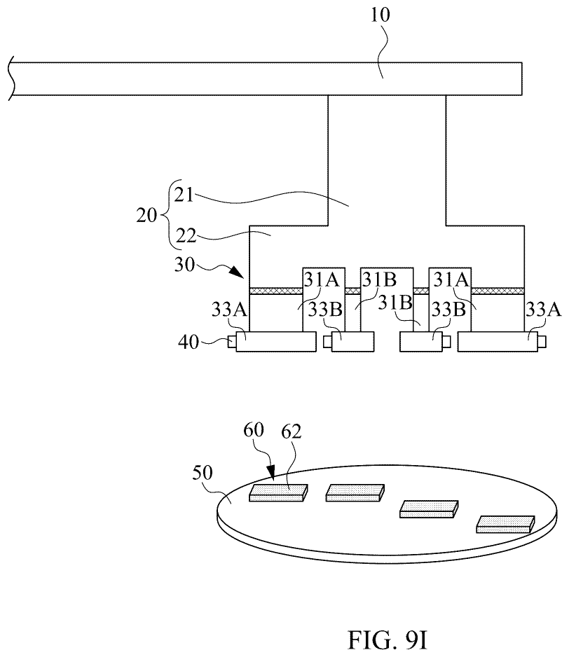

As shown in FIG. 4, the pick-and-place tool according to some embodiments of the present disclosure may further comprise a plurality of position detectors 40. The position detectors 40 can be mounted on the moving arm 20 and/or on the extending arms 30. In some embodiments, the position detectors 40 can be mounted on sides of the platform portion 22 of the moving arm 20. In some embodiments, each of the position detectors 40 can be mounted on a side of the bond head 33. In some embodiments, some of the position detectors 40 can be mounted on the sides of the platform portion 22 of the moving arm 20 while the others of the position detectors 40 can be mounted on a side of the bond head 33 (as shown in FIGS. 9D to 9I). These are, of course, merely examples and are not intended to be limiting. The position detectors 40 is configured to assist the bond heads 33 to adjust their positions targeting predetermined positions on the substrate 50 for placing the device dies 60. The position detector 40 may be an image detector (such as a camera), a near-infrared (NIR) detector, a laser detector or the like. The position detector 40 can transmit the real-time position of the extending arms 30 relative to the predetermined positions on the substrate 50 to the control element, which can control the movement of the telescopic shaft 31 through the electromagnetic induction coils 324 as shown in FIG. 3 to ensure the device dies 60 to be accurately placed on the substrate 50. In some embodiments, the real-time position of the device dies 60 relative to the desired location on the substrate 50 may be transmitted through a wired communication device or a wireless communication device (for example, a radio frequency (RF) transmitter or a Bluetooth (BT) transmitter).

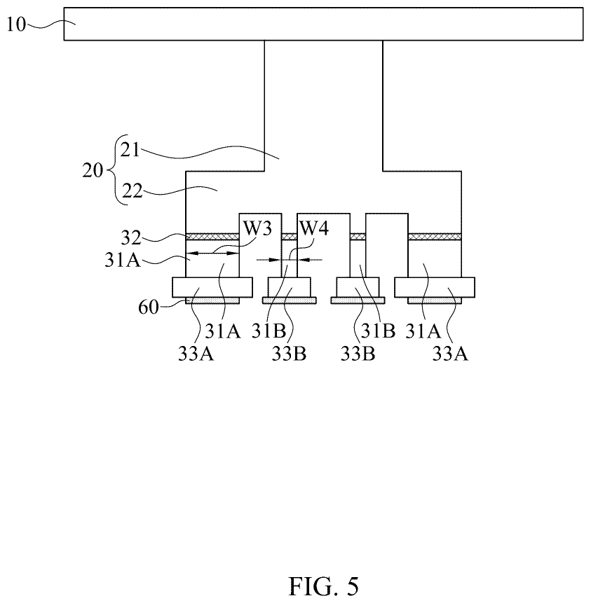

In some embodiments, as shown in FIGS. 1 to 4, the pick-and-place tool may comprise two extending arms 30. Widths of both of the extending arms 30 may be substantially identical. The bond heads 33 of both of the extending arms 30 may have a substantially size. In some embodiments, as shown in FIG. 5, the pick-and-place tool may comprise four extending arms 30, including two large telescopic shafts 31A extending from the bottom of the reversed-T-shape moving arm 20 near an edge of the moving arm 20, and two small telescopic shafts 31B extending from the bottom of the reversed-T-shape moving arm 20 near a center of the moving arm 20, so that the small telescopic shafts 31B are formed between the two large telescopic shafts 31A. In some alternative embodiments, the layout of the large telescopic shafts 31A and small telescopic shafts 31B may be varied according to desired design. The large telescopic shaft 31A has a first width W3 and the small telescopic shaft 31B has a second width W4. In some embodiments, the first width W3 is greater than the second width W4 and a ratio of the first width W3 to the second width W4 may range from about 10:1 to about 10:9. The large telescopic shaft 31A may combine with a larger bond head 33A and the small telescopic shaft 31B may combine with a small bond head 33B. A width of the larger bond head 33A may be larger than the width of the device die 60 while a width of the small bond head 33B may be smaller than the width of the device die 60. These are, of course, merely examples and are not intended to be limiting.

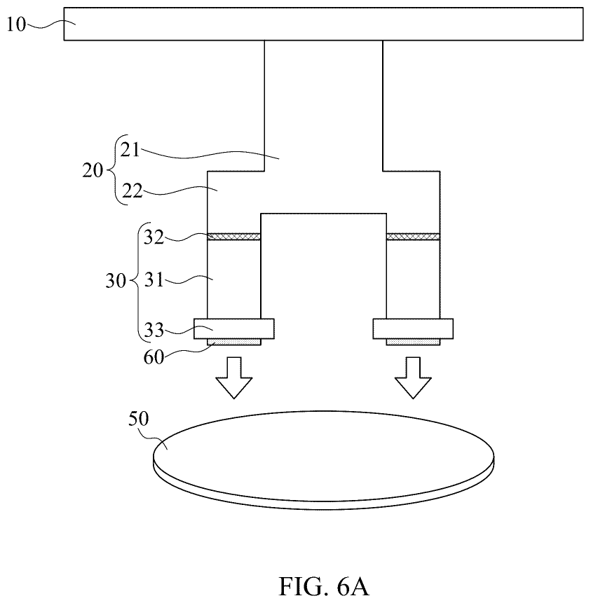

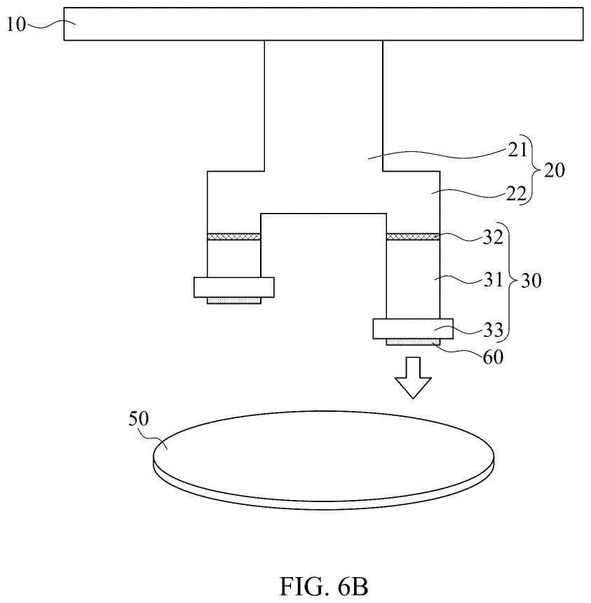

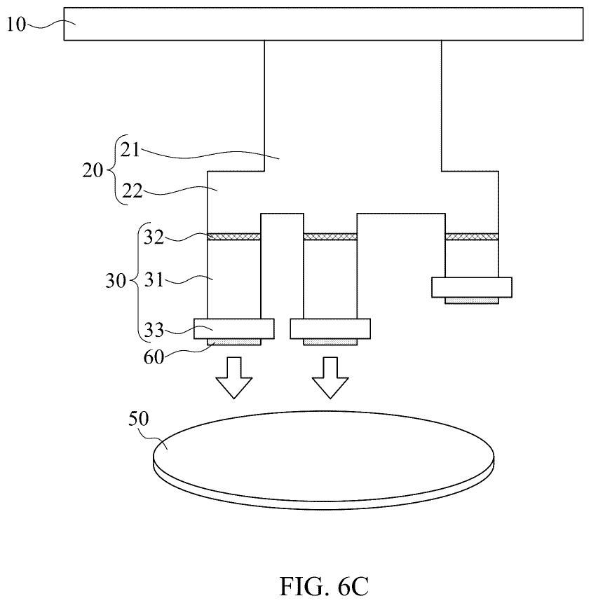

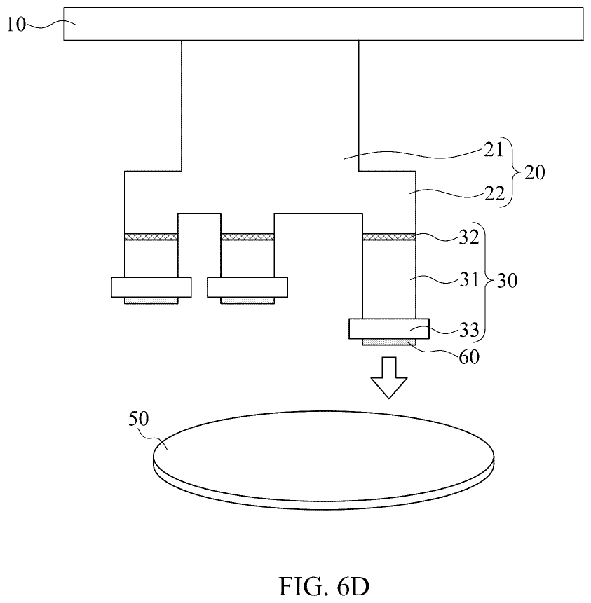

The movement of the telescopic shafts 31 can be separately controlled. In some embodiments, as shown in FIG. 6A, the movement of all the telescopic shafts 31 may controlled to be synchronized. In some embodiments, as shown in FIG. 6B, one of the telescopic shafts 31 may be elongated downward to approach the substrate 50 while the other of the telescopic shafts 31 may stay still or may horizontally move along the guide rail 322. In some embodiments, as shown in FIG. 6C, two of the telescopic shafts 31 may be elongated downward to approach the substrate 50 while the other of the telescopic shafts 31 may stay still or may horizontally move along the guide rail 322. In some embodiments, as shown in FIG. 6D, one of the telescopic shafts 31 may be elongated downward to approach the substrate 50 while the other two of the telescopic shafts 31 may stay still or may horizontally move along the guide rail 322.

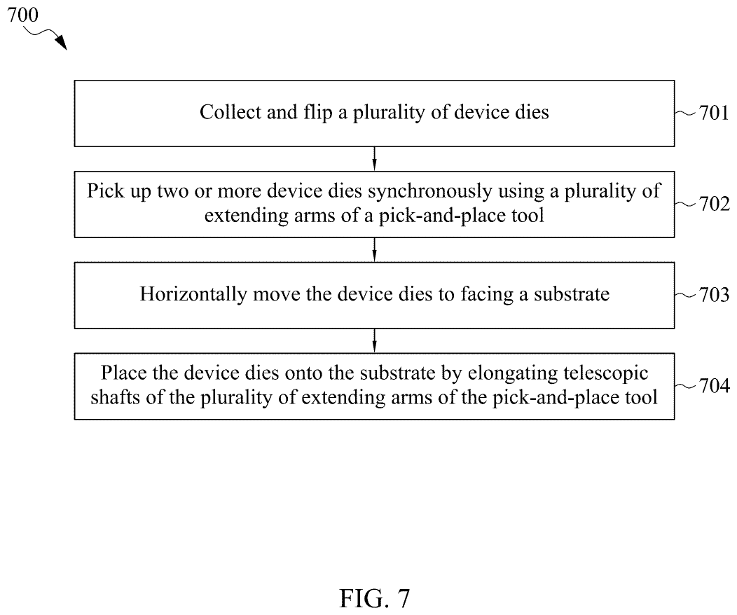

FIG. 7 is a flowchart representing a process 700 for picking and placing device dies according to various aspects of the present disclosure. In some embodiments, the process 700 for fabricating a package includes a number of operations (701, 702, 703 and 704). The process 700 for picking and placing device dies will be further described according to one or more embodiments. It should be noted that the operations of the process 700 may be rearranged or otherwise modified within the scope of the various aspects. It should further be noted that additional processes may be provided before, during, and after the process 700, and that some other processes may be only briefly described herein. FIGS. 8A to 8H and FIGS. 9A to 9AI are diagrammatic perspective views illustrating various stages in the process 700 for picking and placing device dies according to aspects of one or more embodiments of the present disclosure.

With reference to FIGS. 8A to 8D, the process 700 begins at operation 701 where a plurality of device dies 60 are collected and flipped. The plurality of device dies 60 can be provided on a carrier 71 (such as a wafer) as shown in FIG. 8A while a first surface 61 of each device dies 60 faces upward and a second surface 62 of each device dies 60, opposite to the first surface 61, is attached onto the carrier 71; a plurality of flippers 72 can be used to collect several device dies 60 synchronously or non-synchronously as shown in FIGS. 8B and 8C, so the first surface of each device dies 60 is attached to the flipper 72 and the second surface of each device dies 60 detached from the carrier 71 and faces down; and several device dies 60 can be turned over synchronously or non-synchronously as shown in FIG. 8D. In some embodiments, each of the plurality of flippers 72 has a mounting support 721 and a vacuum tip 722 mounted on an end of the mounting support 721. Application of a vacuum produced by a vacuum pump causes the vacuum tip 722 to pick up the device die 60. The mounting support 721 of the flipper 72 can be rotated so that the second surface 62 of each device die 60 can face up. The number of the flippers 72 correspond to the number of the extending arms 30 of the pick-and-place tool to be used in the following operation 702.

The process 700 continues with operation 702 where the pick-and-place tool of the present disclosure as shown in FIGS. 1 to 4 can be used to synchronously pick up several device dies 60 from the flippers 72. As shown in FIG. 8D, the moving arm 20 of the pick-and-place tool is located at a first position of the gantry 10 to allow the bond heads 33 of the plurality of extending arms 30 to face the second surfaces 62 of the device dies 60 flipped by the flipper 72. As shown in FIG. 8E, the second surfaces 62 of the device dies 60 can be respectively attached to the bond heads 33 and the first surfaces 61 of the device dies 60 face down.

At operation 703 as shown in FIGS. 8E and 8F, the moving arm 20 horizontally moves along the gantry 10 to a second position of the gantry 10 to allow the device dies 60 attached onto the bond heads 33 to face a substrate 50. The telescopic shaft 31 can horizontally move along the guide rail 322, which is driven by the electromagnetic induction coils 324 controlled by the control element receiving a signal transmitted from the position detector 40 concerning the real-time position of the device dies 60 relative to the predetermined position on the substrate 50 so as to ensure the device dies 60 to be accurately placed on the substrate 50.

At operation 704 as shown in FIG. 8G, the device dies 60 can be placed onto the substrate 50 by synchronously elongating the telescopic shafts 31 toward the predetermined positions on the substrate 50 until the first surfaces 61 of the device dies 60 are attached to the predetermined positions on the substrate 50. The bond head 33 can be detached from the device dies 60 to leave the device dies 60 on the substrate 50 as shown in FIG. 8H. Therefore, the second surface 62 of each device die 60 attached to the substrate 50 faces up.

In some alternative embodiments as shown in FIG. 6B, the device dies 60 can be placed onto the substrate 50 by sequentially elongating the telescopic shafts 31 toward the predetermined positions on the substrate 50, so that the device dies 60 can be placed onto the substrate 50 in sequence.

In some another embodiments as shown in FIGS. 9A to 9I, the pick-and-place tool of the present disclosure used in such embodiments may comprise more than two extending arms 30 so as to further increase the efficiency in picking and placing the device dies 60.

At operation 701, a plurality of device dies 60 can be provided on a carrier 71 (such as a wafer) as shown in FIG. 9A; four flippers 72 can be used to collect four device dies 60 provided on the carriers 71 as shown in FIGS. 9B and 9C; and these four device dies 60 can be turned up by rotating the flippers 72 as shown in FIG. 9D. The flippers 72 may collect four device dies 60 synchronously or non-synchronously and may turn the device dies 60 over synchronously or non-synchronously. In some embodiments, the flippers 72 may collect and turn over the four device dies 60 synchronously to save time.

At operation 702, the pick-and-place tool comprising four extending arms 30 are used to synchronously pick up several device dies 60 from the flippers 72 as shown in FIG. 9D. The pick-and-place tool comprises four extending arms 30 including two large telescopic shafts 31A located near an edge of the moving arm 20 and two small telescopic shafts 31B located near a center of the moving arm 20. Each large telescopic shaft 31A combines with a larger bond head 33A and each small telescopic shaft 31B combines with a small bond head 33B. The moving arm 20 of the pick-and-place tool is located at a first position of the gantry 10 to allow four bond heads 33A and 33B of the four extending arms 30 to face the device dies 60 flipped by the flipper 72. As shown in FIG. 9E, the device dies 60 can be respectively attached to the bond heads 33A and 33B.

At operation 703 as shown in FIGS. 9E and 9F, the moving arm 20 horizontally moves along the gantry 10 to a second position of the gantry 10 to allow the four device dies 60 attached onto the bond heads 33A and 33B to face a substrate 50. A position detector 40 can be mounted on a side of each of the bond heads 33A and 33B and assists the bond heads 33A and 33B to adjust their positions facing predetermined positions on the substrate 50. The telescopic shaft 31A and 31B can horizontally move along the guide rail 322 in the x-direction, the y-direction and/or xy direction, which is driven by the electromagnetic induction coils 324, so that the device dies 60 can be bonded onto the predetermined positions on the substrate 50.

At operation 704, two of the telescopic shafts 31A and 31B can be synchronously elongated toward the predetermined positions on the substrate 50 to bond the device dies 60 on the predetermined positions as shown in FIG. 9G; then the telescopic shafts 31A and 31B without attaching the device dies 60 can be retracted while the other two of the telescopic shafts 31A and 31B can be synchronously elongated toward the predetermined positions on the substrate 50 to bond the device dies 60 onto the predetermined positions as shown in FIG. 9H. After the device dies 60 are firmly bonded onto the predetermined positions on the substrate 50, the bond heads 33A and 33B can be detached from the device dies 60 to leave the device dies 60 on the substrate 50 as shown in FIG. 9I. In some alternative embodiments, all of the four telescopic shafts 31A and 31B can be synchronously elongated toward the predetermined positions on the substrate 50 to bond these four device dies 60 onto the predetermined positions. In some alternative embodiments, the large telescopic shafts 31A with the larger bond heads 33A can be elongated to place the device dies 60 onto the substrate 50 synchronously while the small telescopic shafts 31B with the small bond heads 33B can be elongated to place the device dies 60 onto the substrate 50 synchronously.

In some another embodiments, four of the telescopic shafts 31A and 31B can be synchronously elongated toward the predetermined positions on the substrate 50 so that all the device dies 60 attached onto the telescopic shafts 31A and 31B can be simultaneously bonded onto the substrate 50. In some another embodiments, three of the telescopic shafts 31A and 31B can be synchronously elongated toward the predetermined positions on the substrate 50 while the remaining one of the telescopic shafts 31A and 31B can be individually elongated toward the predetermined position on the substrate 50 later. In some another embodiments, one of the telescopic shafts 31A and 31B can be elongated toward the predetermined positions on the substrate 50 while the remaining three of the telescopic shafts 31A and 31B can be synchronously elongated toward the predetermined position on the substrate 50 later. In some another embodiments, each of the telescopic shafts 31A and 31B can be individually elongated toward the predetermined position on the substrate 50 so that all the device dies 60 attached onto the telescopic shafts 31A and 31B can be separately bonded onto the substrate 50.

The number and the size of the telescopic shafts 31 used in the process 700 of the present disclosure can be varied according to required design. In some embodiments as shown in FIGS. 6C and 6D, a pick-and-place tool including three extending arms 30, each with one telescopic shaft 31, can be used in the process of the present disclosure. The three telescopic shafts 31 can be elongated synchronously or in any sequence. These are, of course, merely examples and are not intended to be limiting.

Due to the plurality of extending arms 30, the pick-and-place tool of the present disclosure can pick and place several device dies 60 so as to increase the throughput of the pick-and-place process by about 30% or greater. In addition, each of the extending arms 30 can fine tune die alignment so as to maintain or even improve the accuracy of the placement. With the assistance of the position detectors 40, the bond heads 33 can accurately place the device dies 60 onto the substrate 50.

In some embodiments, a process for picking and placing device dies comprises: collecting and flipping a plurality of device dies; picking up the plurality of device dies using a pick-and-place tool, wherein the pick-and-place tool comprises a gantry, a moving arm movably mounted on the gantry, and a plurality of extending arms extending from a bottom of the moving arm, so that each of the plurality of extending arms pick up one of the plurality of device dies; horizontally moving the plurality of device dies to face a substrate by horizontally moving the moving arm along the gantry; horizontally moving a telescopic shaft of each of the plurality of extending arms to align each of the plurality of device dies with a predetermined position on the substrate; and vertically moving the telescopic shaft of each of the plurality of extending arms toward the predetermined position to bond the plurality of device dies onto the substrate.

In some embodiments, a process for picking and placing device dies comprises: collecting and flipping a plurality of device dies; picking up the plurality of device dies synchronously using a pick-and-place tool; and placing the plurality of device dies onto a substrate using the pick-and-place tool.

In some embodiments, a pick-and-place tool comprises: a gantry; a moving arm horizontally-movably attached to the gantry; and a plurality of extending arms extending from a bottom of the moving arm and each of the plurality of extending arms comprising: a telescopic shaft extended from the bottom of the moving arm and being horizontally movable and vertically retractable; and a bond head extending from a bottom end of the telescopic shaft.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A process for picking and placing device dies, comprising:
collecting and flipping a plurality of device dies;
picking up the plurality of device dies using a pick-and-place tool, wherein the pick-and-place tool comprises a gantry, a moving arm movably mounted on the gantry, and a plurality of extending arms extending from a bottom of the moving arm, so that each of the plurality of extending arms pick up one of the plurality of device dies;
horizontally moving the plurality of device dies to face a substrate by horizontally moving the moving arm along the gantry;
horizontally moving a telescopic shaft of each of the plurality of extending arms to align each of the plurality of device dies with a predetermined position on the substrate; and
vertically moving the telescopic shaft of each of the plurality of extending arms toward the predetermined position to bond the plurality of device dies onto the substrate.

2. The process of claim 1, wherein the moving arm is capable of horizontally moving within a first distance and the telescopic shaft is capable of horizontally moving within a second distance, and wherein the first distance is less than the second distance.

3. The process of claim 2, wherein a ratio of the second distance to the first distance ranges from about 1:10 to about 1:1,000.

4. The process of claim 1, wherein the moving arm is capable of vertically moving within a third distance and the telescopic shaft is capable of vertically moving within a fourth distance, and wherein the third distance is greater than the fourth distance.

5. The process of claim 4, wherein a ratio of the fourth distance to the third distance ranges from about 1:2 to about 1:1,000.

6. The process of claim 1, wherein the telescopic shafts of the plurality of extending arms have a same width or different widths.

7. The process of claim 1, wherein the plurality of extending arms are separated from each other with a distance, which is equal to or greater than a width of each of the plurality of device dies.

8. A process for picking and placing device dies, comprising:
collecting and flipping a plurality of device dies;
picking up the plurality of device dies synchronously using a pick-and-place tool; and
placing the plurality of device dies onto a substrate using the pick-and-place tool.

9. The process of claim 8, wherein the plurality of device dies are collected and flipped by a plurality of flippers synchronously, and wherein a number of the plurality of device dies is identical to a number of the flippers.

10. The process of claim 8, wherein the plurality of device dies are picked up by a plurality of extending arms of the pick-and-place tool, and wherein a number of the plurality of device dies is identical to a number of the plurality of extending arms.

11. The process of claim 10, wherein placing the plurality of device dies onto the substrate comprises horizontally moving each of the plurality of extending arms so as to align each of the plurality of device dies with a predetermined position on the substrate; and vertically moving the plurality of extending arms toward the substrate so as to bond the plurality of device dies onto the substrate.

12. The process of claim 11, wherein the plurality of extending arms vertically move toward the substrate synchronously so as to bond the plurality of device dies onto the substrate simultaneously.

13. The process of claim 11, wherein the plurality of extending arms vertically move toward the substrate sequentially so as to bond the plurality of device dies onto the substrate in sequence.

14. The process of claim 8, wherein after picking up the plurality of device dies synchronously, the plurality of device dies horizontally move to face the substrate.

15. A pick-and-place tool, comprising:
a gantry;
a moving arm horizontally-movably attached to the gantry; and
a plurality of extending arms extending from a bottom of the moving arm and each of the plurality of extending arms comprising:
a telescopic shaft extended from the bottom of the moving arm and being horizontally movable and vertically retractable; and
a bond head extending from a bottom end of the telescopic shaft.

16. The pick-and-place tool of claim 15, wherein the moving arm is capable of horizontally moving within a first distance and the telescopic shaft is capable of horizontally moving within a second distance, and wherein the first distance is less than the second distance;
and wherein the moving arm is capable of vertically moving within a third distance and the telescopic shaft is capable of vertically moving within a fourth distance, and wherein the third distance is greater than the fourth distance.

17. The pick-and-place tool of claim 16, wherein a ratio of the second distance to the first distance ranges from about 1:10 to about 1:1,000; and a ratio of the fourth distance to the third distance ranges from about 1:2 to about 1:1,000.

18. The pick-and-place tool of claim 15, wherein each of the plurality of extending arms further comprises at least one shaft controller mounted between the moving arm 20 and the telescopic shaft so as to connect the moving arm with the telescopic shaft and to drive the telescopic shaft to move horizontally and/or vertically.

19. The pick-and-place tool of claim 15, further comprising a plurality of position detectors mounted on the moving arm and/or on the extending arms to detect positions of the bond head.

20. The pick-and-place tool of claim 15, wherein the moving arm has a reversed-T cross section and comprises:
a shaft portion having a first end, which is horizontally-movably mounted on the gantry and is vertically retractable; and
a platform portion extending from a second end of the shaft portion opposite to the first end, and having a width larger than a width of the shaft portion,
wherein the telescopic shaft of each of the plurality of extending arms extends from a bottom of the platform portion of the moving arm.
